(19) United States
(12) Patent Application Publication
(10) Pub. No.: US 2024/0290878 A1
(43) Pub. Date: Aug. 29, 2024

(54) VERTICAL POWER SEMICONDUCTOR DEVICE

(71) Applicant: Infineon Technologies AG, Neubiberg (DE)

(72) Inventors: Guang Zeng, München (DE); Dethard Peters, Höchstadt (DE)

(21) Appl. No.: 18/585,167

(22) Filed: Feb. 23, 2024

(30) Foreign Application Priority Data
Feb. 28, 2023 (DE) 102023104891.0

(51) Int. Cl. H01L 29/78; H01L 29/66

(52) U.S. Cl. CPC H01L 29/7811; H01L 29/66734

(57) ABSTRACT

A vertical power semiconductor device includes a semiconductor body having first and second opposite surfaces. A subdivision of an area of the semiconductor body at the first surface includes: a transistor cell area having transistor cells in the semiconductor body; an edge termination area surrounding the transistor cell area, the semiconductor body including a termination structure in the edge termination area; a gate line area between the transistor cell area and the edge termination area, the gate line area including a gate line over the semiconductor body; and a source or emitter line area between the gate line area and the edge termination area. The source or emitter line area includes transistor cells in the semiconductor body, and a source or emitter line over the semiconductor body.

### TECHNICAL FIELD

The present disclosure is related to a vertical power semiconductor device, in particular to a vertical power semiconductor device comprising an edge termination area in a semiconductor body.

### BACKGROUND

Technology development of new generations of vertical power semiconductor devices, e.g. metal oxide semiconductor field effect transistors (MOSFETs), or insulated gate bipolar transistors (IGBTs), or junction field effect transistors (JFETs), aims at improving electric device characteristics and reducing costs by shrinking device geometries. Although costs may be reduced by shrinking device geometries, a variety of tradeoffs and challenges have to be met when increasing device functionalities per unit area. For example, complying with reliability requirements requires design optimization when increasing device functionalities per unit area.

Thus, there is a need for an improved vertical power semiconductor device.

### SUMMARY

An example of the present disclosure relates to a vertical power semiconductor device. The vertical power semiconductor device includes a semiconductor body having a first surface and a second surface opposite to the first surface. A subdivision of an area of the semiconductor body at the first surface includes a transistor cell area comprising transistor cells in the semiconductor body. The subdivision of an area of the semiconductor body at the first surface further includes an edge termination area surrounding the transistor cell area. The semiconductor body further includes a termination structure in the edge termination area. The subdivision of an area of the semiconductor body at the first surface further includes a gate line area between the transistor cell area and the edge termination area. The gate line area includes a gate line over the semiconductor body. The subdivision of an area of the semiconductor body at the first surface further includes a source or emitter line area between the gate line area and the edge termination area. The source or emitter line area includes transistor cells in the semiconductor body, and a source or emitter line over the semiconductor body.

Another example of the present disclosure relates to a method of manufacturing a vertical power semiconductor device. The method includes providing a semiconductor body having a first surface and a second surface opposite to the first surface. A subdivision of an area of the semiconductor body at the first surface includes forming a transistor cell area comprising transistor cells in the semiconductor body. The subdivision of an area of the semiconductor body at the first surface further includes forming an edge termination area surrounding the transistor cell area. The semiconductor body includes a termination structure in the edge termination area. The subdivision of an area of the semiconductor body at the first surface further includes forming a gate line area between the transistor cell area and the edge termination area. The gate line area includes a gate line over the semiconductor body. The subdivision of an area of the semiconductor body at the first surface further includes forming a source or emitter line area between the gate line area and the edge termination area. The source or emitter line area includes transistor cells in the semiconductor body, and a source or emitter line over the semiconductor body.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of vertical power semiconductor devices and together with the description serve to explain principles of the examples. Further examples are described in the following detailed description and the claims.

FIG. 1A is a top view for illustrating an example of a vertical power semiconductor device.

FIG. 1B is an exemplary cross-sectional view along line AA′ of FIG. 1A.

FIG. 2 is an exemplary top view for illustrating another example of a vertical power semiconductor device.

FIG. 3 is an exemplary cross-sectional view along line AA′ of FIG. 2.

FIG. 4 is an exemplary top view around line along CC′ of FIG. 2.

FIG. 5 is an exemplary cross-sectional view along line BB′ of FIG. 2.

FIG. 6 is an exemplary top view around line along BB′ of FIG. 2.

### DETAILED DESCRIPTION

In the following detailed description, reference is made to the accompanying drawings, which form a part hereof and in which are shown by way of illustrations specific examples of vertical power semiconductor devices. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact may be a non-rectifying electrical junction.

Ranges given for physical dimensions include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of the present disclosure relates to a vertical power semiconductor device. The vertical power semiconductor device includes a semiconductor body having a first surface and a second surface opposite to the first surface. A subdivision of an area of the semiconductor body at the first surface may include a transistor cell area comprising transistor cells in the semiconductor body. The subdivision of an area of the semiconductor body at the first surface may further include an edge termination area surrounding the transistor cell area. The semiconductor body may include a termination structure in the edge termination area. The subdivision of an area of the semiconductor body at the first surface may further include a gate line area between the transistor cell area and the edge termination area. The gate line area may include a gate line over the semiconductor body. The subdivision of an area of the semiconductor body at the first surface may further include a source or emitter line area between the gate line area and the edge termination area. The source or emitter line area may include transistor cells in the semiconductor body, and a source or emitter line over the semiconductor body.

The vertical power semiconductor device may be part of or may be at least one of: an integrated circuit, a discrete semiconductor device, or a semiconductor module, for example. The semiconductor device may be used in applications related to power transmission and distribution, automotive and transport, renewable energy, consumer electronics, and other industrial applications. The vertical power semiconductor device may be or a may include an insulated gate field effect transistor (IGFET) such as a metal oxide semiconductor field effect transistor (MOSFET), an insulated gate bipolar transistor (IGBT), or a junction field effect transistor (JFET), for example.

The vertical power semiconductor device may have a load current flow between the first surface and the second surface opposite to the first surface. The first surface may be a front surface or a top surface of the semiconductor body, and the second surface may be a back surface or a rear surface of the semiconductor body, for example. The semiconductor body may be attached to a lead frame via the second surface, for example. Over the first surface of the semiconductor body, interconnects may be arranged on a contact pad structure of a wiring area for electrically connecting device elements in the semiconductor body to elements, e.g. other semiconductor devices, outside of the semiconductor device, for example.

The vertical power semiconductor device may be configured to conduct currents of more than 1 A, or more than 10 A, or more than 30 A, or more than 50 A, or more than 75 A, or even more than 100 A. The vertical power semiconductor device may be further configured to block voltages between load terminals, e.g. between collector and emitter of an IGBT, or between drain and source of a MOSFET or JFET, in the range of several hundreds of up to several thousands of volts, e.g. 400 V, 650V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The semiconductor body may include or consist of a semiconductor material from the group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). The semiconductor body may comprise or may be an epitaxially deposited semiconductor material. Separately or in combination, the semiconductor body may comprise a growth substrate. For example, vertical power semiconductor device may be based on a semiconductor body from a crystalline SiC material. For example, the semiconductor material may be 2H-SiC (SiC of the 2H polytype), 6H-SIC, 3C-SiC or 15R-SiC. According to an example, the semiconductor material is silicon carbide of the 4H polytype (4H-SiC). The semiconductor body may consist of a semiconductor substrate or may include or consist of a semiconductor substrate having none, one or more than one SiC layers, e.g. epitaxially grown SiC layers, thereon.

For realizing a desired current carrying capacity, the vertical power semiconductor device may be designed by a plurality of parallel-connected transistor cells in the transistor cell area. The parallel-connected transistor cells may, for example, be transistor cells formed in the shape of a strip or a strip segment. The transistor cells can also have any other shape, e.g. circular, elliptical, polygonal such as hexagonal or octahedral. The transistor cells may be arranged in the transistor cell area of the semiconductor body. The transistor cell area may be an active area where a source region of a FET or JFET at the first surface and a drain region of the FET or JFET are arranged opposite to one another along the vertical direction. Likewise, the transistor cell area may be an active area where an emitter region of an IGBT at the first surface and a collector region of the IGBT are arranged opposite to one another along the vertical direction. In the transistor cell area, a load current may enter or exit the semiconductor body of the FET, or JFET, or IGBT, e.g. via contact plugs on the first surface of the semiconductor body. For example, the transistor cell area may be defined by an area where source contact plugs or emitter contact plugs are placed over the first surface.

The edge termination area includes the termination structure. In a blocking mode or in a reverse biased mode of the FET, or JFET, or IGBT, the blocking voltage between the transistor cell area and a field-free region laterally drops across the termination structure in the edge termination area. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example. The wiring area may laterally adjoin to a passivation area that may be arranged over the edge termination area of a vertical power semiconductor device, for example.

A source or emitter contact may be part of a wiring area over the semiconductor body. The wiring area may include one or more than one, e.g. two, three, four or even more wiring levels. Each wiring level may be formed by a single one or a stack of conductive layers, e.g. metal layer(s). For example, the wiring levels may include at least one of Cu, Au, AlCu, Ag, or alloys thereof. The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, e.g. metal lines or contact areas, of different wiring levels to one another. The source or emitter contact may be formed by one or more elements of the wiring area over the first surface. For example, the source or emitter contact may include a source or emitter pad that may be used as a bonding area. The source or emitter contact may also include further conductive structures e.g. contact plugs or lines, between the transistor cell area at the first surface and the source or emitter pad, for example. Likewise, the drain or collector contact may be formed by one or more elements of the wiring area over the second surface.

The gate line area between the transistor cell area and the edge termination area may include a gate line over the semiconductor body. An interlayer dielectric may be arranged between the gate line and the first surface of the semiconductor body. The interlayer dielectric may be part of a patterned dielectric layer or a dielectric layer stack. Other parts of the patterned dielectric layer or dielectric layer stack may also be used in other areas of the vertical power semiconductor device. For example, when forming the transistor cells based on gate trenches, a part of the patterned dielectric layer or dielectric layer stack in the transistor cell area may be formed on top of the gate trenches for electrically insulating a gate electrode in the gate trenches from a source or emitter contact over the gate trenches. The gate line may be formed as a part of the wiring area, and may be formed in a wiring level, e.g. the wiring level closest to the first surface, that may also be used for the source or emitter contact or line. The gate line may be a so-called gate runner. For example, the gate line aims at providing a low-ohmic interconnection from a gate pad to the gate electrodes (e.g. planar gate electrodes or trench gate electrodes) in the transistor cells. Therefore, the gate line may branch off from the gate pad and at least partly surround the transistor cell area. The gate electrodes of the transistor cells may be electrically connected to the gate line in the gate line area, for example via a part of a patterned planar doped polycrystalline layer that may also be used in other parts of the vertical power semiconductor device (e.g. for electrically connecting gate electrodes of the transistor cells in the source or emitter line area to the gate line in the gate line area).

The source or emitter line area between the gate line area and the edge termination area. The source or emitter line area may include transistor cells in the semiconductor body, and a source or emitter line over the semiconductor body. An interlayer dielectric comprising contact openings may be arranged between the source or emitter line and the first surface of the semiconductor body. The interlayer dielectric may be part of a patterned dielectric layer or a dielectric layer stack. Other parts of the patterned dielectric layer or dielectric layer stack may also be used in other areas of the vertical power semiconductor device. For example, when forming the transistor cells based on gate trenches, a part of the patterned dielectric layer or a dielectric layer stack in the transistor cell area may be formed on top of the gate trenches for electrically insulating a gate electrode in the gate trenches from a source or emitter contact over the gate trenches. Another part of the patterned dielectric layer or a dielectric layer stack in the gate line area may be arranged between the gate line and the first surface of the semiconductor body. The source or emitter line may be formed as part of the wiring area, and may be formed in a wiring level, e.g. the wiring level closest to the first surface, that may also be used for the source or emitter contact and/or the gate line. For example, the source or emitter line may be electrically connected to the transistor cells in the source or emitter line area, e.g. to a p-doped region at the first surface of the semiconductor body in the source or emitter line area in case of n-channel transistor cells. The source or emitter line may aim at charging/discharging a pn-junction formed by the termination structure, e.g. JTE, in the edge termination area.

By providing the transistor cells in the source or emitter line area, a pn or pin diode current may be suppressed by a channel current of the transistor cells. Thus, a bipolar current may only contribute to the current flow at very high current levels. This allows for balancing a current distribution between the transistor cell area and the source or emitter line area. Thus, a surge current capability of the vertical power semiconductor device in an operation mode with open channel may be improved. Moreover, since the pn or pin diode in the source or emitter line area is suppressed by a MOS channel of the transistor cells in the source or emitter line area, the risk of bipolar degradation in vertical power semiconductor devices based on SiC may also be reduced. In addition, since the source or emitter line area includes active transistor cells, e.g. MOSFET cells, or IGBT cells, or JFET cells, chip area of the source or emitter line area may contribute to reduce the total area-specific on-state resistance, RDSon.

For example, the source or emitter line area may fully surround the transistor cell area.

For example, the vertical power semiconductor device may further include a source or emitter electrode or contact over the first surface of the semiconductor body in the transistor cell area. The source or emitter electrode or contact, the gate line and the source or emitter line may be parts of a wiring layer, e.g. metal layer, over the semiconductor body.

For example, the vertical power semiconductor device of the preceding claim may further include a gate pad being another part of the wiring layer, wherein the gate line merges into the gate pad. The gate pad may be laterally arranged between the source or emitter line and the transistor cell area.

For example, the gate line area may be free of transistor cells. In the gate line area, a p-doped region may be formed at the first surface. A vertical doping concentration profile of the p-doped region may, at least with respect to part of a vertical extent of the p-doped region, coincide with a vertical doping concentration profile of a p-doped region in other parts of the vertical power semiconductor device, e.g. in the transistor cell area.

For example, the semiconductor body may include at least a pn junction diode in the gate line area. A p-doped anode region of the pn junction diode may adjoin to a dielectric layer on the first surface of the semiconductor body. The dielectric layer may be part of a patterned dielectric layer or a dielectric layer stack, the dielectric layer separating the gate line and the p-doped anode region. An n-doped cathode region of the pn junction diode may include an n-doped drift region and may adjoin to the second surface of the semiconductor body. For example, the p-doped anode region of the pn junction diode may adjoin to the dielectric layer on the first surface of the semiconductor body in case of n-channel transistor cells in the transistor cell area.

For example, the transistor cells may include trench gate structures, and a bottom side of the trench gate structures may have a smaller vertical distance to the first surface than a bottom side of the p-doped anode region. A vertical doping concentration profile of the p-doped anode region between a first level at a bottom side of the p-doped anode region and a second level at a bottom side of the trench gate structures may be equal to a vertical doping concentration profile between the first level and the second level of a p-doped region adjoining to a bottom side of the trench gate structures in the transistor cell area. The p-doped region adjoining to a bottom side of the trench gate structures in the transistor cell area may be configured to screen a gate dielectric from high electric field strengths that may occur when high blocking voltages are applied between the load terminals of the vertical power semiconductor device, for example.

For example, the p-doped anode region may merge into a p-doped region of a closest transistor cell in the source or emitter line area. Likewise, the p-doped anode region may merge into a p-doped region of the closest transistor cell in the transistor cell area. This may allow for improving blocking voltage capabilities in a transition area between the transistor cell area and the edge termination area, for example.

For example, a vertical doping concentration profile of the p-doped anode region and a vertical doping concentration profile of a p-doped region of the closest transistor cell in the source or emitter line area may coincide. This may allow for using a common ion implantation process for forming p-doped regions having different technical purposes in different areas of the vertical power semiconductor device.

For example, a width of the source or emitter line may be in a range from 1 to 20 times a minimum lateral extent of a transistor cell. The width of the source or emitter line may also vary along a lateral direction, for example.

For example, the transistor cells may each include trench gate structures. A trench gate structure in the source or emitter line area may be merged with a trench gate structure in the transistor cell area by a connecting trench gate structure extending across the gate line area. for example.

For example, the transistor cells may each include trench gate structures. A gate electrode of a trench gate structure in the source or emitter line area may be electrically connected to the gate line by a connecting line over the first surface. The connecting line may extend from the gate electrode to the gate line.

For example, the connecting line may include doped polycrystalline silicon. The doped polycrystalline material may be part of a patterned planar doped polycrystalline layer. Another part of the patterned planar doped polycrystalline layer may be arranged in the gate line area for providing an electric contact to the gate electrode in gate trenches extending from the transistor cell area into the gate line area, for example.

For example, each of the transistor cells may include a trench gate structure. Each of the transistor cells may further include a p-doped diode region adjoining to a bottom side and to a first sidewall of the trench gate structure, a p-doped body region and an n-doped source or emitter region, wherein the p-doped body region and the n-doped source or emitter region may adjoin to a second sidewall of the trench gate structure.

Details with respect to structure, or function, or technical benefit of features described above with respect to a FET, or JFET, or IGBT likewise apply to the exemplary methods described herein. Processing the semiconductor body may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

An example of the present disclosure relates to a method for manufacturing a vertical power semiconductor device. The method includes providing a semiconductor body having a first surface and a second surface opposite to the first surface. A subdivision of an area of the semiconductor body at the first surface may include forming a transistor cell area comprising transistor cells in the semiconductor body. The subdivision of an area of the semiconductor body at the first surface may further include forming an edge termination area surrounding the transistor cell area. The semiconductor body may include a termination structure in the edge termination area. The subdivision of an area of the semiconductor body at the first surface may further include forming a gate line area between the transistor cell area and the edge termination area. The gate line area may include a gate line over the semiconductor body. The subdivision of an area of the semiconductor body at the first surface may further include forming a source or emitter line area between the gate line area and the edge termination area. The source or emitter line area may include transistor cells in the semiconductor body, and a source or emitter line over the semiconductor body.

For example, the method may further include forming a source or emitter ion implantation mask on the first surface of the semiconductor body. The source or emitter ion implantation mask may fully cover the gate line area and may include mask openings in the source or emitter line area and in the transistor cell area. The method may further include introducing dopants through the mask openings into the semiconductor body by ion implantation.

For example, the method may further include forming a trench from the first surface into the SiC semiconductor body. The trench may laterally extend from the transistor cell area across the gate line area and into the source or emitter line area.

For example, forming the gate line, the source or emitter line, and a source or emitter electrode or pad over the first surface of the semiconductor body may include forming a wiring layer over the first surface, and patterning the wiring layer in wiring layer parts. The wiring layer parts may include the gate line, the source or emitter line, and the source or emitter electrode.

The examples and features described above and below may be combined. Functional and structural details (e.g. materials, dimensions) described with respect to the examples above shall likewise apply to the examples illustrated in the figures and described further below.

The examples and features described above and below may be combined.

More details and aspects are mentioned in connection with the examples described above or below. Processing a semiconductor body, e.g. a wafer, may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

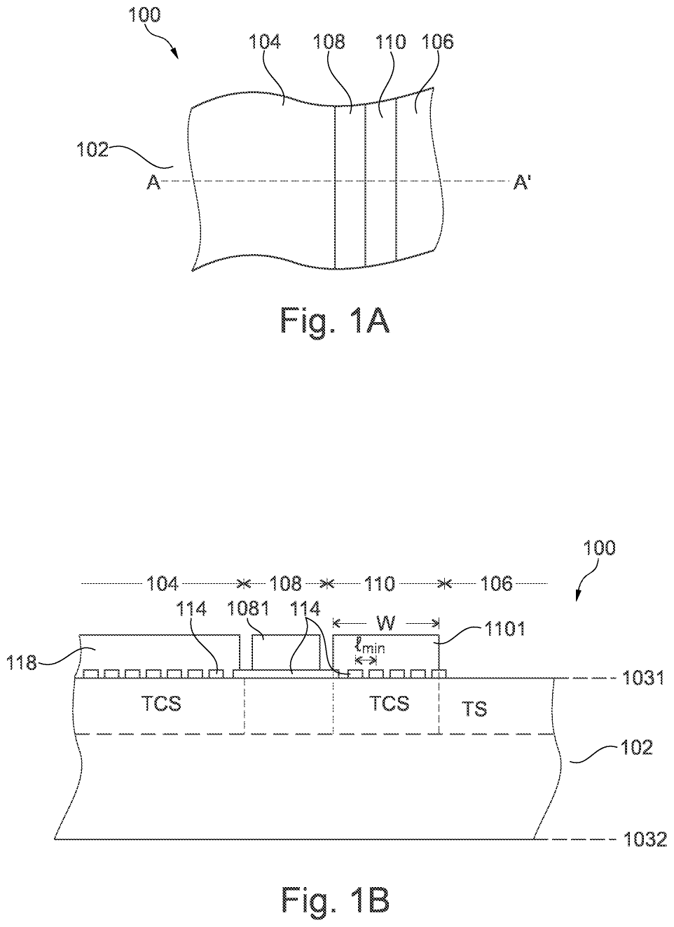

FIG. 1A schematically and exemplarily shows a partial top view of a vertical power semiconductor device 100. FIG. 1B schematically and exemplarily shows a partial cross-sectional view of the vertical power semiconductor device 100 of FIG. 1A along line AA′.

Referring to FIGS. 1A and 1B, the vertical power semiconductor device 100 includes a semiconductor body 102, e.g. SiC substrate. The semiconductor body 102 has a first surface 1031, e.g. a front or top surface. A second surface 1032, e.g. rear or back surface, of the semiconductor body 102 is located opposite to the first surface 1031. An area or portion of the semiconductor body 102 at the first surface 1031 is divided into sub-areas and includes a transistor cell area 104. In the transistor cell area 104, transistor cells TCs are formed. The specific structure of the transistor cells TCs depends on the type of vertical power semiconductor device, e.g. JFET, or MOSFET, or IGBT, and also depends on the specific layout chosen for the transistor cells TCs. The schematic illustration in FIGS. 1A, 1B may include any of specific transistor cell layouts and is simplified in that the area comprising the transistor cells TCs is denoted by a dashed line.

The vertical power semiconductor device 100 further includes an edge termination area 106. In the semiconductor body 102 of the edge termination area 106, a termination structure TS is formed. The schematic illustration in FIG. 1B may include any of specific termination structure(s) TCs and is simplified in that the area comprising the termination structure(s) TCs is denoted by a dashed line.

Subdivision of an area of the semiconductor body 102 at the first surface 1031 further includes a gate line area 108 laterally arranged between the transistor cell area 104 and the edge termination area 106. The gate line area 108 includes a gate line 1081 over the semiconductor body 102. An interlayer dielectric 114 electrically insulates the gate line 1081 from the semiconductor body 102.

A source or emitter line area 110 is arranged between the gate line area 108 and the edge termination area 106. Transistor cells TCs are formed in the semiconductor body 102 of the source or emitter line area 110. In the source or emitter line area 110, a source or emitter line 1101 is arranged over the semiconductor body 102. For example, layouts of the transistor cells in the transistor cell area 104 and in the source line area 110 may be equal.

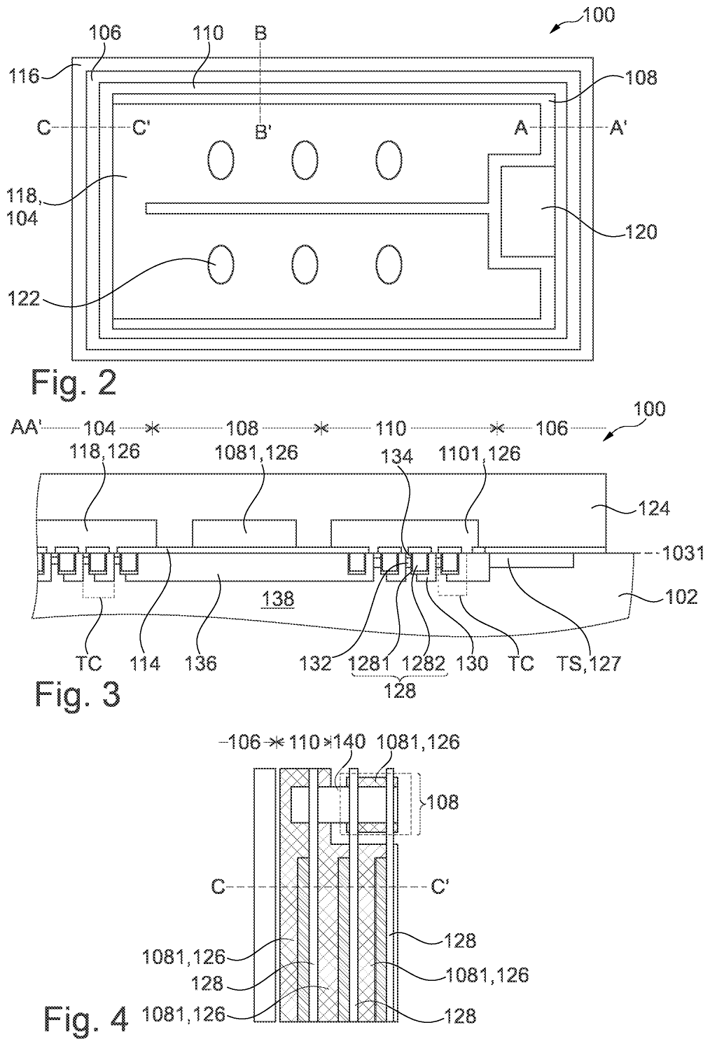

The schematic top view of FIG. 2 is an exemplary and schematic illustration of a vertical power semiconductor device 100.

A kerf area 116 laterally surrounds the edge termination area 106. In the exemplary layout of FIG. 2, the source or emitter line area 110 fully surrounds the transistor cell area 104 and a source or emitter line 1101 in the source or emitter line area 110 turns, at one side of the transistor cell area 104, into a source or emitter pad or electrode 118 located in the transistor cell area 104. The gate line area 108 partly surrounds the transistor cell area 104 and a gate line 1081 in the gate line area 108 turns into a gate pad 120 at a side of the transistor cell area 104 that is opposite to the side where the source or emitter line 1101 turns into the source or emitter pad 118. Bond wires 122 on the source pad or emitter pad 118 are electrically connected to the to the source pad or emitter pad 118.

An exemplary cross-sectional view along line AA′ of FIG. 2 is illustrated in FIG. 3.

In the schematic cross-sectional view of FIG. 3, a passivation structure 124, e.g. an imide, is arranged over the first surface 1031 of the semiconductor body 102. A first wiring layer 126 over the first surface 1031 is patterned and sub-divided into the source or emitter line 1101, the gate line 1081, and the source or emitter pad 118. The interlayer dielectric 114 is arranged between the first wiring layer 126 and the first surface 1031 of the semiconductor body 102.

In the edge termination area 106, the termination structure TS includes a Junction Termination Extension (JTE) 127.

Transistor cells TCs are formed in the source or emitter line area 110 and in the transistor cell area 104. Each of the transistor cells TCs includes a trench gate structure 128 comprising a gate dielectric 1281 and a gate electrode 1282. A p-doped diode region 130 adjoins to a sidewall of the trench gate structure 128. The p-doped diode region 130 in the source or emitter line area 110 merges into the JTE 127 in the edge termination area 106. The p-doped diode region 130 may include a plurality of p-doped sub-regions. Vertical doping concentration profiles of neighboring ones of the p-doped subregions may overlap along the vertical direction, for example. Each of the transistor cells TC further includes a p-doped body region 132 adjoining to a sidewall of the trench gate structure 128 that is opposite to the sidewall where the p-doped diode region 130 adjoins to the trench gate structure 128. Likewise, an n-doped source region 134 adjoins to a sidewall of the trench gate structure 128 that is opposite to the sidewall where the p-doped diode region 130 adjoins to the trench gate structure 128.

The semiconductor body further includes a pn junction diode in the gate line area 108. The pn junction diode includes a p-doped anode region 136 adjoining to the interlayer dielectric 114 on the first surface 1031 of the semiconductor body 102. A bottom side of the trench gate structures 128 has a smaller vertical distance to the first surface 1031 than a bottom side of the p-doped anode region 136. The p-doped anode region 136 merges into the p-doped diode region 130 of a closest transistor cell TC in the transistor cell area 104. An n-doped cathode region of the pn junction diode may be formed as part of an n-doped drift region 138 of the vertical power semiconductor device 100.

A schematic top view of a part of the vertical power semiconductor device 100 in an area around line CC′ of FIG. 2 is illustrated in the top view of FIG. 4. The schematic top view illustrates only some of the regions depicted in the cross-sectional view of FIG. 3. A gate electrode of a trench gate structure 128 in the source or emitter line area 110 is electrically connected to the gate line 1081 by a connecting line 140 over the first surface 1031. The connecting line 140 extends from the gate electrode to the gate line 1081. For example, the connecting line 140 may be arranged between the first surface 1031 and the first wiring layer 126. The connecting line 140 may comprise doped polycrystalline silicon. For example, a part of a bottom side of the connecting line may be in contact with the gate electrode of the trench gate structures 128 in the source or emitter line area 110. A part of a top side of the connecting line 140 may be in contact with the gate line 1081 in the gate line area 108 area, for example.

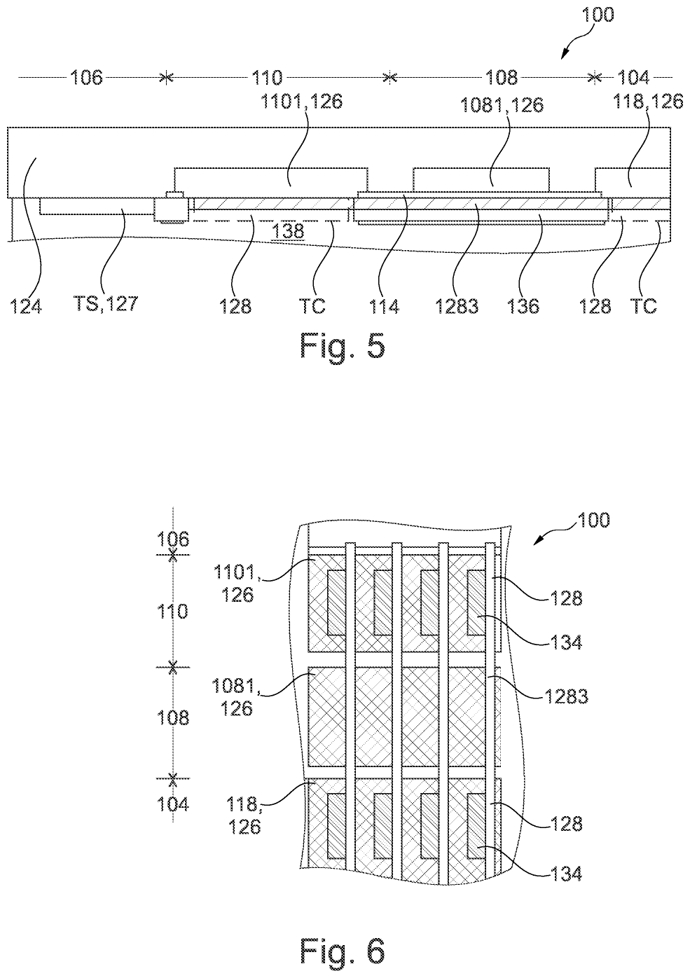

An exemplary cross-sectional view along line BB′ of FIG. 2 is illustrated in FIG. 5. A schematic top view of a part of the vertical power semiconductor device 100 illustrated in FIG. 5 is shown in FIG. 6. The schematic top view illustrates only some of the regions depicted in the cross-sectional view.

In the schematic cross-sectional and top views of FIGS. 5 and 6, a trench gate structure 128 in the source or emitter line area 110 is merged with a trench gate structure 128 in the transistor cell area 104 by a connecting trench gate structure 1283 extending across the gate line area 108.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

The aspects and features mentioned and described together with one or more of the previously detailed examples and figures, may as well be combined with one or more of the other examples in order to replace a like feature of the other example or in order to additionally introduce the feature to the other example.

What is claimed is:

1. A vertical power semiconductor device, comprising:
a semiconductor body having a first surface and a second surface opposite to the first surface, wherein a subdivision of an area of the semiconductor body at the first surface comprises:
a transistor cell area comprising transistor cells in the semiconductor body;
an edge termination area surrounding the transistor cell area, the semiconductor body comprising a termination structure in the edge termination area;
a gate line area between the transistor cell area and the edge termination area, the gate line area comprising a gate line over the semiconductor body; and
a source or emitter line area between the gate line area and the edge termination area, the source or emitter line area comprising transistor cells in the semiconductor body, and a source or emitter line over the semiconductor body.

2. The vertical power semiconductor device of claim 1, wherein the source or emitter line area fully surrounds the transistor cell area.

3. The vertical power semiconductor device of claim 1, further comprising a source or emitter electrode over the first surface of the semiconductor body in the transistor cell area, wherein the source or emitter electrode, the gate line, and the source or emitter line are parts of a wiring layer over the semiconductor body.

4. The vertical power semiconductor device of claim 3, further comprising a gate pad being another part of the wiring layer, wherein the gate line merges into the gate pad, and wherein the gate pad is laterally arranged between the source or emitter line and the transistor cell area.

5. The vertical power semiconductor device of claim 1, wherein the gate line area is free of transistor cells.

6. The vertical power semiconductor device of claim 1, wherein the semiconductor body comprises at least a pn junction diode in the gate line area, wherein a p-doped anode region of the pn junction diode adjoins a dielectric layer on the first surface of the semiconductor body, the dielectric layer separating the gate line and the p-doped anode region, and wherein an n-doped cathode region of the pn junction diode includes an n-doped drift region and adjoins the second surface of the semiconductor body.

7. The vertical power semiconductor device of the claim 6, wherein the transistor cells comprise trench gate structures, and wherein a bottom side of the trench gate structures has a smaller vertical distance to the first surface than a bottom side of the p-doped anode region.

8. The vertical power semiconductor device of claim 6, wherein the p-doped anode region merges into a p-doped region of a closest transistor cell in the source or emitter line area.

9. The vertical power semiconductor device of claim 6, wherein a vertical doping concentration profile of the p-doped anode region and a vertical doping concentration profile of a p-doped region of a closest transistor cell in the source or emitter line area coincide.

10. The vertical power semiconductor device of claim 1, wherein a width of the source or emitter line is in a range from 1 to 20 times a minimum lateral extent of a transistor cell.

11. The vertical power semiconductor device of claim 1, wherein the transistor cells comprise trench gate structures, and wherein a trench gate structure in the source or emitter line area is merged with a trench gate structure in the transistor cell area by a connecting trench gate structure that extends across the gate line area.

12. The vertical power semiconductor device of claim 1, wherein the transistor cells comprise trench gate structures, and wherein a gate electrode of a trench gate structure in the source or emitter line area is electrically connected to the gate line by a connecting line over the first surface, the connecting line extending from the gate electrode to the gate line.

13. The vertical power semiconductor device of claim 12, wherein the connecting line comprises doped polycrystalline silicon.

14. The vertical power semiconductor device of claim 13, wherein each of the transistor cells comprises a trench gate structure, a p-doped diode region adjoining to a bottom side and to a first sidewall of the trench gate structure, a p-doped body region, and an n-doped source or emitter region, and wherein the p-doped body region and the n-doped source or emitter region adjoin to a second sidewall of the trench gate structure.

15. A method of manufacturing a vertical power semiconductor device, the method comprising:
providing a semiconductor body having a first surface and a second surface opposite to the first surface,
wherein for a subdivision of an area of the semiconductor body at the first surface, the method further comprises:
forming a transistor cell area comprising transistor cells in the semiconductor body;
forming an edge termination area surrounding the transistor cell area, the semiconductor body comprising a termination structure in the edge termination area;
forming a gate line area between the transistor cell area and the edge termination area, the gate line area comprising a gate line over the semiconductor body; and
forming a source or emitter line area between the gate line area and the edge termination area, the source or emitter line area comprising transistor cells in the semiconductor body, and a source or emitter line over the semiconductor body.

16. The method of claim 15, wherein forming the transistor cells in the source or emitter line area and in the transistor cell area comprises:
forming a source or emitter ion implantation mask on the first surface of the semiconductor body, wherein the source or emitter ion implantation mask fully covers the gate line area and includes mask openings in the source or emitter line area and in the transistor cell area; and
introducing dopants through the mask openings into the semiconductor body by ion implantation.

17. The method of claim 15, further comprising forming a trench from the first surface into the semiconductor body, wherein the trench laterally extends from the transistor cell area across the gate line area and into the source or emitter line area.

18. The method of claim 15, further comprising forming a source or emitter electrode over the first surface of the semiconductor body.

19. The method of claim 18, wherein forming the gate line, the source or emitter line, and the source or emitter electrode comprises:
forming a wiring layer over the first surface; and
patterning the wiring layer in wiring layer parts, the wiring layer parts including the gate line, the source or emitter line, and the source or emitter electrode.
